(19) United States
(12) Patent Application Publication
(10) Pub. No.: US 2017/0256908 A1
(43) Pub. Date: Sep. 7, 2017

(54) Method For Operating A Power Management Device, Power Management Device And Computer Program

(71) Applicant: Siemens Aktiengesellschaft, Muenchen (DE)

(72) Inventors: Thomas Lehmann, Erlangen (DE); Johannes Reinschke, Nuernberg (DE)

(73) Assignee: Siemens Aktiengesellschaft, Muenchen (DE)

(21) Appl. No.: 15/507,972

(22) PCT Filed: Sep. 3, 2015
(86) PCT No.: PCT/EP2015/070150

§ 371 Date: Mar. 1, 2017

(30) Foreign Application Priority Data
Sep. 8, 2014 (DE) 10 2014 217 930.0

(51) Int. Cl. H01S 5/065; G01J 3/10; H01S 5/10; H01S 5/40; H01S 5/00; H01S 5/042

(52) U.S. Cl. CPC H01S 5/0656; H01S 5/0064; H01S 5/0085; H01S 5/0427; H01S 5/1096; H01S 5/4006; G01J 3/10; G01N 2021/399

(57) ABSTRACT

A method for operating a power management device for controlling an operating device connected to a power supply network, in which the maximum demanded and/or provided output of the controlled operating device is at least 3 kW, is disclosed. An information data set is received which describes coupling information or a temporal progression of coupling information from a server device associated with a network provider of a power supply network, the coupling information describing a relationship between a device load of the operating device and a target variable to be optimized. A load profile is determined which describes a predicted temporal progression of the device load by optimizing the load profile with respect to the target variable. The load profile is provided to the server device, and the power management device may control the operating device according to a default value which is predetermined based on the load profile.

### CROSS-REFERENCE TO RELATED APPLICATIONS

This application is a U.S. National Stage Application of International Application No. PCT/EP2015/070150 filed Sep. 3, 2015, which designates the United States of America, and claims priority to DE Application No. 10 2014 217 930.0 filed Sep. 8, 2014, the contents of which are hereby incorporated by reference in their entirety.

### TECHNICAL FIELD

The invention relates to a method for operating a power management device for controlling an operational facility connected to a power supply network, the maximum power level demanded and/or supplied by the controlled operational facility being at least 3 kW. The invention also relates to an associated power management device and a computer program.

### BACKGROUND

Large-scale buildings and industrial plants often have automation systems which control individual devices and device groups. These automation systems can comprise power management devices which can monitor an energy consumption of controlled and non-controlled devices and can control the controlled devices, in the case of an active power management device, such that an energy efficiency is increased and/or load spikes are limited.

Operational facilities such as large-scale buildings and industrial plants also increasingly have energy-generating devices, for example, photovoltaic systems, wind power systems or similar. In addition, the proportion of renewable energy types in power supply networks is generally increasing and an energy generation by means of renewable energy types is not freely controllable. Whereas it is usual in conventional power supply networks to adapt an energy generation to the energy consumption required, this is not possible in all cases when operational facilities can act as both consumers and generators of energy and when renewable energy types are used. In addition, an optimization of the energy efficiency of a plurality of individual operational facilities which are connected to a power supply network does not necessarily lead to an optimum energy efficiency of the totality of the operational facilities.

### SUMMARY

One embodiment provides a method for operating a power management device for controlling an operational facility connected to a power supply network, wherein the maximum power level demanded and/or supplied by the controlled operational facility is at least 3 kW, comprising the steps: (a) receiving an information data set which describes a coupling information item or a temporal variation of the coupling information, from a server device which is associated with a network operator of a power supply network or with a power supplier, wherein the coupling information describes a relationship between a facility load caused by the operational facility and a target variable to be optimized during an optimizing interval, (b) determining a load profile which describes a predicted temporal variation of the facility load of the operational facility during the optimizing interval, by optimizing the load profile with respect to the target variable by means of the power management device, (c) providing the load profile to the server device, and (d) controlling the operational facility by means of the power management device in the optimizing interval dependent upon a specified value for the facility load pre-set by the load profile for the momentary operating time point.

In one embodiment, steps a) to c) are carried out at a pre-set time spacing before the optimizing interval.

In one embodiment, steps a) to c) are carried out at a plurality of temporally spaced time points before the optimizing interval.

In one embodiment, the operational facility is controlled by means of the power management device in the optimizing interval dependent upon a difference value giving the difference between the specified value for the facility load pre-set by the load profile for the momentary operating time point and a momentary actual value of the facility load.

In one embodiment, the information data set describes a difference information item or a temporal variation of a difference information item, wherein the difference information item describes a relationship between the difference value and the target variable, wherein the operational facility is controlled dependent upon the target variable.

In one embodiment, the power management device is configured to receive a load adjustment request from the server device, and adjust the load profile in accordance with the load adjustment request.

In one embodiment, the power management system is configured to establish, and transfer to the server device, a tolerance profile based on at least one operating parameter influencing the facility load of the operational facility and/or at least one property of the operational facility influencing the facility load of the operational facility, wherein the tolerance profile describes a temporal variation of a tolerance region of the facility load in the optimizing interval, wherein the load adjustment request is determined based on the tolerance profile such that the adjusted load profile lies within the tolerance region.

In one embodiment, the information data set describes at least one tolerance information item or a temporal variation of the tolerance information, wherein the tolerance information describes a relationship between adjustments of the load profile based upon possible load adjustment requests and the target variable, wherein the tolerance profile is determined dependent upon the tolerance information item.

In one embodiment, the information data set describes a power maximum information item which describes a relationship between the target variable and the maximum of a power level in a pre-set time interval, in particular the optimizing interval, supplied and/or demanded by the operational facility, wherein the determination of the load profile and/or the control of the operational facility takes place dependent upon the power maximum information item.

In one embodiment, the information data set can describe a reactive power information item or a temporal variation of the reactive power information item, wherein he reactive power information item defines a relationship between a reactive power level of the operational facility and the target variable during the optimizing interval, wherein the determination of the load profile and/or the control of the operational facility takes place dependent upon the reactive power information item.

In one embodiment, at least during the optimizing interval, acquisition data concerning a facility load of the operational facility is acquired repeatedly by the power management device and provided to the server device.

In one embodiment, before step a), a configuration data set is transferred by the server device to the power management device, after which the power management system adjusts the determination of the load profile and/or the determination of the tolerance profile and/or the control of the operational facility dependent upon the configuration data set.

In one embodiment at least one time point of the provision of the load profile in relation to the optimizing interval and/or a length of the optimizing interval is pre-set based on the configuration data set.

Another embodiment provides a power management device for controlling an operational facility connected to a power supply network, wherein the maximum power level demanded and/or supplied by the controlled operational facility is at least 3 kW, wherein said power management device is configured for carrying out the method as disclosed above.

Another embodiment provides a computer program stored in non-transitory computer-readable media and executable by a processor to perform the functions of the power management device as disclosed above.

### BRIEF DESCRIPTION OF THE DRAWINGS

Example aspect and embodiments of the invention are described below with reference to the drawings, in which:

FIG. 1 is a schematic representation of a method according to one embodiment of the invention, and

FIG. 2 is a schematic representation of a power management device and its connection to an operational facility and a server device associated with a power supply network.

### DETAILED DESCRIPTION

Embodiments of the invention provide a method for operating a power management device by means of which an energy efficiency in power supply networks can be increased and/or a flexible reaction to changes of the energy quantity generated in the power supply network is possible.

One embodiment provides a method including the following steps:
a. receiving an information data set which describes a coupling information item or a temporal variation of the coupling information, from a server device which is external to the power management device and is associated with a network operator of the power supply network or with a power supplier, the coupling information describing a relationship between a facility load caused by the operational facility and a target variable to be optimized during an optimizing interval,
b. determining a load profile which describes a predicted temporal variation of the facility load of the operational facility during the optimizing interval, by optimizing the load profile with respect to the target variable by means of the power management device,
c. providing the load profile to the server device, and
d. controlling the operational facility by means of the power management device in the optimizing interval dependent upon a specified value for the facility load pre-set by the load profile for the momentary operating time point.

In some embodiments, the power management device is configured to determine a load profile that describes the temporal variation of the facility load during a temporal optimizing interval, this determination taking place dependent upon an information data set provided by a server device which is external to the power management device and is associated with the power supply network or the power supplier. The power supply network can be, in particular, a network for the supply of the operational facility with electrical energy, but also another energy supply network, for example, a gas network or a network in which energy is supplied in the form of heat or steam.

The load profile can represent a sequence of load values for the facility load in order to represent a temporal variation of the facility load. The load values can describe as the facility load a power level needed and/or provided by the operational facility at the time point or in the time interval. The individual power values can be given, for example in kW or MW. The load profile can describe positive facility loads which describe a power level needed and/or negative facility loads which describe a power level provided on the power supply network. By means of the specification of the information data set, the load profile of the operational facility can be adapted to a predicted operating situation in the power supply network. The server device can be operated by an operator of the power supply network or by a power supplier. It can be associated with an energy market, an aggregator which enables a common presence of a plurality of operational facilities on an energy market and/or a virtual generating station which enables a common presence of a plurality of energy suppliers on the energy market. It is achieved, by the information exchange according to the invention, that is, the receipt of the information data set and the provision of the load profile to the server device, that an optimization of the facility loads and thus of the energy generation and of the energy consumption takes place not only locally for an individual operational facility, but also a common optimization of the loads for an entire power supply network or for at least parts of a power supply network is enabled.

The power management device may be configured to optimize the load profile with respect to a target variable, wherein at least one coupling information item which describes a relationship between the facility load and the target variable to be optimized is provided by the server device. The type of target variable defines with respect to which property an optimization is carried out. For example, a target variable can be a predicted CO₂ consumption or a consumption of non-renewable energy types that is minimized. Alternatively or additionally, as the target variable, for example, a proportion of renewable energy types in the energy generation can be maximized. The stated target variables are useful in particular when an operator of an operational facility wishes to participate actively in the increasing of the overall efficiency and thus the environmental friendliness of the power supply network and the operational facilities supplied. Alternatively or in addition, it is possible that by means of a power supplier, a price structure for a power supply is configured such that the operator of an operational facility is prompted to operate the operational facility such that the power supply network with the operational facilities connected thereto is operable particularly efficiently overall and thus also economically. As a target variable, therefore, costs can also be evaluated for an energy type drawn from the power supply network or income for an energy type supplied for the power supply network. On specification of an efficiency-oriented pricing and an optimization of the costs or of the remuneration, this also leads to an increase of the efficiency of the power supply network with the operational facilities connected thereto.

The determination of the load profile can take place by minimizing or maximizing a cost function determining the target variable. In particular, the target variable and thus the cost function can depend on a plurality of factors. In this case, the individual factors can be taken into account as a weighted sum, although non-linear couplings between the factors are also possible.

In the context of the determination of the load profile, pre-set operating parameters and/or properties of the operational facility which are pre-set by the user or by other facilities can be taken into account. For example, during operation of an industrial plant, particular operating times of individual elements of the industrial plant are required in order to achieve a pre-set production quantity. If technical facilities or rooms are climate-controlled, a pre-set temperature range has typically to be maintained. Depending on the type of operational facility, certain pre-set boundary conditions therefore arise which can be taken into account in the optimization of the load profile. The same applies for the control of the operational facility since, here also, the control should always take place such that pre-set requirements are met. The optimization and/or control can therefore take place according to at least one boundary condition.

The coupling information can be, in particular, a proportionality factor between a consumed or supplied energy, which is calculable as, in particular, an integral in portions over the load profile, and the target variable. For example, a CO₂ consumption or a price per kWh can be provided as coupling information. It is herein possible, in particular, to take account of only one effective power. However, the relationship between load profile and target variable and thus the coupling information can also be more complex. For example, a “staggered” proportionality factor can be used wherein, for different energy quantities supplied or consumed, different proportionality factors are provided in portions. The coupling information can, however, also specify or parameterize any desired other functional relationships between the load profile and the target variable.

The optimizing interval can be, in particular, a day, but also a plurality of days, half a day, six hours or the like. It is also possible that apart from the load profile for the optimizing interval further load profiles for longer time periods, in particular for a week, a month or a year are calculated and are provided to the server device. Long-term load profiles enable an operator of the power supply network to plan at an early stage suitable measures, for example, the putting into operation of generating stations, by which the overall effectiveness of the energy supply network can be further increased. In order to calculate the medium-term and long-term prognoses for load profiles, by means of the server devices, further coupling information items can be provided, although it is also possible to determine corresponding medium-term and long-term load profiles exclusively from operating parameters and/or properties of the operational facility itself and to provide them to the server device.

The coupling information can be temporally variable and can change particularly during the optimizing interval. The coupling information can be a coupling information item predicted, in particular, by the server device, dependent upon operating parameters of the power supply network or can be provided by a user of the server device. It can be determined by an evaluation of different information items provided to an operator of the power supply network. The information of the information data set, in particular the coupling information, can be selected so that in the context of the determination of the load profile, a behavior of the operational facility at the power supply network connection that is desired on the power supplier side is favored. If, for example, price information is communicated as coupling information items, low prices can be pre-set for times at which the energy consumption is expected to be lower than the energy production.

The information data set can further comprise a fixed offset which is added to the target variable. This is advantageous in particular if the optimization of the target variable takes place simultaneously with the optimization of other variables, for example, a production quantity in an industrial plant. Variations of the target variable, for example, on the basis of changes in the load profile, are thus differently weighted dependent upon the offset. A corresponding offset can represent, for example, basic costs of a power supply.

The communication between the server device and the power management device can take place, in particular, by means of network-callable functions which are implemented, for example, via SOAP or by means of network protocols which represent network participants as objects with settable or readable properties, for example BACnet or OPC UA. A data exchange is possible, in particular, via the Internet or a VPN. The underlying network can be completely cable-bound, completely cable-free or partially cable-bound and partially cable-free.

Advantageously, the server device also implements possibilities to call data, once provided by the power management device to the server device by means of the power management device, from the server device again. This enables a particularly easy data reconstruction by the power management device, for example, following a re-start or a new configuration of the power management device.

The steps a) to c) of the disclosed method can be carried out at a pre-set time spacing before the optimizing interval. In particular, the load profile can be communicated at a pre-set time spacing before the optimizing interval, corresponding to the overall optimizing interval, two thirds of the optimizing interval, half of the optimizing interval or a third of the optimizing interval. In particular, in the disclosed method, only one minimum time spacing can be pre-set, so that an earlier transfer of the load profile is possible.

The steps a) to c) can be carried out at a plurality of temporally spaced time points before the optimizing interval. The information data set transferred by the server device can be determined on repeated execution of the steps a) to c), in particular, dependent upon a previously communicated load profile. Advantageously, a server device communicates with a plurality of power management devices and an information data set transferred in the context of a repetition to one of these power management devices is determined dependent upon the load profiles provided and/or further information of a plurality, or all, of these power management devices. Thus, an iterative optimization of the target variable is achieved in a general grouping of a server device and one or more power management devices.

The operational facility can be controlled by means of the power management device in the optimizing interval dependent upon a difference value giving the difference between the specified value for the facility load pre-set by the load profile for the momentary operating time point and a momentary actual value of the facility load. For example, an actual value of the facility load can depend on activities of one or more operators of an operational facility. For example, some consumers can be switched on or off manually. In addition, the facility load of a plurality of energy-converting elements of the operational facilities depends upon externally pre-set factors. For example, the facility load of an air conditioning system or a photovoltaic system can depend on the weather. In the disclosed method, it is advantageous if the operational facility is operated as far as possible so that the difference value is minimized and the operational facility therefore behaves on the network side as defined in the previously determined load profile.

A strict minimization of the difference value can lead to an operational facility being unable to fulfill its function entirely and, for example, the production of an industrial plant falls, air conditioning of rooms can only take place partially, or the like. Likewise, in different operational situations of the power supply network, a deviation from the load profile can severely reduce the efficiency of the power supply network and in other operational situations, can have almost no influence on the efficiency of the power supply network. It is therefore advantageous if the information data set describes a difference information item or a temporal variation of a difference information item, the difference information item describing a relationship between the difference value and the target variable, the operational facility being controlled dependent upon the target variable. In the context of the control system, it can therefore be taken into account how strongly a deviation from the load profile affects a target variable to be optimized. For example, it can be determined how strongly a CO₂ emission rises or how far a proportion of a renewable energy type falls when the facility load of the operational facility deviates from the load profile. The difference information item can also be a price information item with which it can be calculated by the power management device what costs a deviation from the load profile causes. The disclosed method thus makes it possible in the context of the control system of the operational facility to take into account to what extent a deviation from the load profile is economically and/or ecologically suitable, when considering the functionalities provided through the deviation from the load profile. The difference information item can describe any type of relation between the target variable and the difference value, that is, in particular a proportionality or a portion-wise proportionality with a staggered proportionality factor.

The power management device may be configure to receive a load adjustment request from the server device, and adjust the load profile in accordance with the load adjustment request. A load adjustment request can take place even before the start of the optimizing interval and/or during the optimizing interval. Load adjustment requests can be transmitted, for example, by the server device if an energy supplied and/or consumed in the overall power supply network severely deviates from a predicted energy consumed and/or supplied for the corresponding time point, so that adjustments are required in order to compensate for the consumed and supplied energy. While it is typically possible to compensate for an imbalance between consumed and supplied energy via external energy markets, it can be economically and/or ecologically more suitable to adapt a load profile of one or more connected operational facilities by means of a load adjustment request.

The power management device may be configured to establish and transfer to the server device a tolerance profile based on at least one operating parameter influencing the facility load of the operational facility and/or at least one property of the operational facility influencing the facility load of the operational facility. The tolerance profile may describe a temporal variation of a tolerance region of the facility load in the optimizing interval. The load adjustment request may then be determined based on the tolerance profile such that the adjusted load profile lies within the tolerance region. Many operational facilities can readily adapt a load profile in some operational situations without losing any functionality. Thus, for example, in operational facilities batteries can be provided which can output or absorb additional energy in the short term. Heating and cooling systems can also temporally displace heating and cooling intervals at least slightly in very many usage situations, due to a thermal inertia of systems, so that tolerances can be provided for the load profile. Through the provision of a suitable tolerance profile by the power management system to the server device and a usage of load adjustment requests adapted to the respective tolerance profiles on one or more power management systems, a particularly ecological and economic balancing of consumed and provided energy in power supply networks can be achieved.

Advantageously, information can be provided to the power management system over the extent to which it is ecologically and/or economically worthwhile to provide corresponding tolerances. Therefore, the information data set can describe at least one tolerance information item or a temporal variation of the tolerance information, wherein the tolerance information describes a relationship between adjustments of the load profile based upon possible load adjustment requests and the target variable, the tolerance profile being determined dependent upon the tolerance information item. Items of tolerance information can be, in particular, different relationships between the adjustments and the target variable for different adjustment directions of the load profile, that is, toward a higher power level needed by the operational facility or a lower power level provided by the operational facility or vice versa. The tolerance information item can, in particular, be a proportionality factor wherein the proportionality factor can be different for differently severe deviations, so that a staggered proportionality is achieved.

The information data set can describe a power maximum information item which describes a relationship between the target variable and the maximum of a power level in a pre-set time interval, in particular the optimizing interval, supplied and/or demanded by the operational facility, the determination of the load profile and/or the control of the operational facility taking place dependent upon the power maximum information item. High power spikes through an operational facility are typically particularly disadvantageous for an effective operation of a power supply network with the consumers associated therewith. Therefore, under some circumstances, additional costs that are set for power spikes are charged by power suppliers. It is thus advantageous if, in the context of the information data set, information items are provided over the extent to which power spikes in the load profile determined or in the context of the control system impair the optimization of the target variable, which means in particular the extent to which economic and/or ecological disadvantages are caused by high power spikes.

The information data set can describe a reactive power information item or a temporal variation of the reactive power information item, the reactive power information item defining a relationship between a reactive power level of the operational facility and the target variable during an optimizing interval, the determination of the load profile and/or the control of the operational facility taking place dependent upon the reactive power information item. Power supply networks are additionally loaded by reactive power levels. Depending on the operational state of the power supply network, this loading can have different effects. It is therefore advantageous to take into account the severity of the impairment of the power supply network by means of reactive power levels in the context of the determination of the load profile and/or the control of the operational facility.

At least during the optimizing interval, acquisition data concerning a facility load of the operational facility can be acquired repeatedly by the power management device and provided to the server device. Specific data concerning the actual load profile of the operational facility, which can be used in particular for charging and/or optimizing purposes, is thus provided to the server device.

Before step a), a configuration data set can be transferred by the server device to the power management system, after which the power management system adjusts the determination of the load profile and/or the determination of the tolerance profile and/or the control of the operational facility dependent upon the configuration data set. Spacings between a determination of acquisition data or a provision of this data can be adjusted. The configuration data set corresponds to the technical counterpart of a “contract” by means of which the technical parameters of the data exchange between the power management device and the server device are specified. It is possible that a corresponding configuration data set is derived automatically or manually from specifications of a contract between an operator of the power management system or the operational facility and an operator of the power supply network.

The configuration data set can comprise, in particular, information relating to a validity period of the configuration data set. Additionally or alternatively, the configuration data set can define at least one time point of the provision of the load profile in relation to the optimizing interval and/or a length of the optimizing interval. Also, a, particularly periodically recurring, start of an optimizing interval, the length of an interval for the power maximum determination, time points at which further prediction information for medium-term or long-term load profiles are to be communicated by the power management, measuring intervals for measuring data and/or data formats for information items transferred by means of the information data set and/or the load and/or tolerance profiles can be determined by the configuration data set.

Other embodiments provide a power management device for controlling an operational facility connected to a power supply network, the maximum power level demanded and/or supplied by the controlled operational facility being at least 3 kW, wherein the power management device is configured to carry out the disclosed method. The power management device can comprise means for receiving information data comprising, in particular, cost information from a server device operated by a network operator or a power supplier-operated server device and means for transmitting a predicted load profile for the operational facility to the server device. The means for transmitting and receiving can be provided, in particular, together in the form of a communication module which can be provided both as an independent device (gateway) in a separate housing and also integrated, for example, into a computer device of the power management device. The communication module therefore forms an interface which provides a communication possibility between the power management device and the network operator/network supplier, or more precisely the server device situated at that site. For this purpose, hardware and software means can be present at the communication module, which configure the communication module for receiving the information data set, for providing or transmitting the load profile and possibly the broadly described data exchange, in particular in relation to the configuration data set in the context of the initialization. In addition, the power management device can comprise means for determining a load profile according to step b) of the disclosed method and means for controlling the operational facility according to step d) of the disclosed method.

The disclosed power management device can be a part of an automation system for the operational facility, although it is also possible that the power management device is configured separately from an automation device and communicates therewith, for example, via network-callable functions. Functions for a communication between the server device and the power management device can be an integral component of the power management device. However, it is also possible to configure the power management device such that a communication with the server device is provided by means of a separate module which communicates, for example, via a network connection, in particular via network-callable functions, with other components of the power management device which serve for determining the load profile and/or the control of the operational facility. Features which have been described in relation to the disclosed method are similarly transferable to the disclosed power management device.

Other embodiments provide a computer program wherein on execution of the computer program on a computer device, the computer device forms an inventive power management device. Features described in relation to the disclosed method or the disclosed power management device can be transferred similarly with the advantages described there to the disclosed computer program.

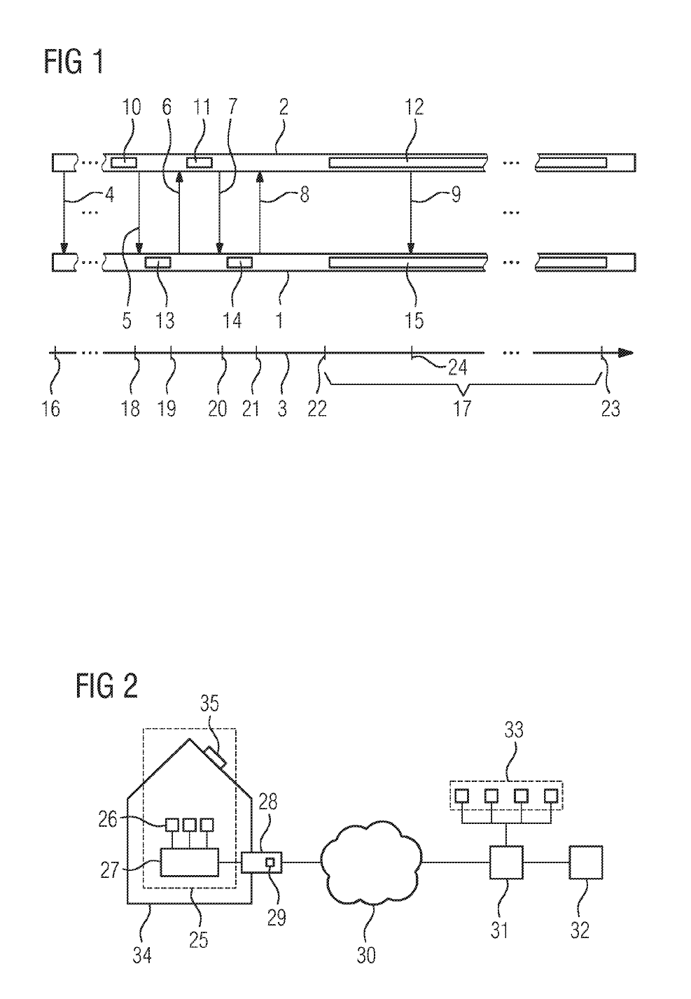

FIG. 1 shows schematically the temporal sequence of a method for operating a power management device 1 for controlling an operational facility (not shown) connected to a power supply network. The power level demanded and/or supplied by the controlled operational facility is at least 3 kW. FIG. 1 shows schematically a temporal variation wherein at the left figure edge, temporally early and at the right figure edge, temporally late processes are represented. Also represented schematically are the power management device 1, a server device 2 associated with the power supply network and, in particular, operated by the operator of the power supply network, and a time axis 3. Illustrated by the arrows 4, 5, 6, 7, 8, 9 are respective communication processes between the power management device 1 and the server device 2. In the domain of the power management device 1 and of the server device 2, the time regions 10, 11, 12 and 13, 14, 15, respectively are shown, in which the power management device 1 and the server device 2 carry out essential functions for the method described.

The method starts at the time point 16 with a transfer, represented by the arrow 4, of a configuration data set from the server device 2 to the power management device 1. The communication between the power management device 1 and the server device 2 takes place during this and the communication processes described below by means of a call of network-callable functions, which are called up, for example, via SOAP.

The transfer of a configuration data set from the server device 2 to the power management device 1 can take place therein that the server device 2 calls a network-callable function of the power management device 1 in order to set corresponding configuration data to the relevant values. Alternatively, the power management device 1 could call a network-callable function implemented by the server device 2, in order to retrieve the configuration data set from the server device 2. Advantageously, both of the functions described are implemented, wherein the method can normally be started by a call of a network-callable function of the power management device 1 for setting the configuration data, however, on a data loss by the power management device, for example on a new start, relevant configuration data can be retrieved again from the server device 2. The further data transfers represented by the arrows 5, 7, and 9 from the server device 2 to the power management device 1 also take place so that for the respectively transferred data, the respectively described retrieval and setting functions are implemented on the server device 2 or on the power management device 1. A data transfer from the power management device 1 to the server device 2, as represented by the arrows 6 and 8 takes place in this way in principle, wherein in this case a setting function is implemented for setting the data at the server device 2 and a fetching function, on the calling of which data is made available to the server device 2, on which the power management device 1 is implemented.

The configuration data set stipulates, in particular, the time points and time intervals that are used in the further procedure. In particular, the configuration data set represents technically relevant parameters of a contract between an operator of the power management device 1 and the associated operational facility and an operator of the power supply network or a dealer who supplies energy via the power supply network for the operational facility and/or receives energy therefrom. By means of the server device 2, the data of the configuration data set can be generated, in particular automatically, from an electronically existing contract data set.

The configuration data set comprises, in particular, a start and end point of the contract and a time interval within which, in each case, a maximum of the power demanded by the operational facility is to be determined. By means of the configuration data set, the power management device can be assigned a unique identification which may comprise, in particular, a contract ID and a facility ID. In the context of the configuration data set, data formats and the units allocated to the transferred numerical values are set. The units allocated to the numerical values can alternatively also be transferred in separate data fields in the context of the further communications represented by the arrows 5, 6, 7, 8, 9.

Further data of the configuration data set can define a length of an optimizing interval 17 and the relative position of the time points 18, 19, 20, 21, 22 at which the data transfers represented by the arrows 5, 6, 7, 8 between the power management device 1 and the server device 2 take place or at which the optimizing interval 17 begins. For example, the time point 18 can be set in relation to the time point 22 and the time point 9 can be set in relation to the time point 18, etc. The position of the time points 18, 19, 20, 21, 22 relative to one another is set in each case by a temporal spacing from one of the other time points.

In addition, with the configuration data set, interval lengths and time points for transfer of a long-term and a short-term load profile are communicated, wherein the respective intervals are longer than the optimizing interval, for example, one month for a short-term load profile and one or more years for a long-term load profile. The determination and transfer of the short-term and long-term load profiles is not shown. Short-term and long-term load profiles are ascertained at the time points determined by the configuration data set by means of a statistical evaluation of operational data gathered during continuing operation of the operational facility and transferred to the server device 2.

The configuration data set also describes at what intervals acquisition data relating to a facility load of the operational facility should be acquired by the power management device 1 and provided to the server device 2. The acquisition and provision of the acquisition data is not shown in FIG. 1 and can take place continuously in the background or alternatively only in the optimizing interval.

The transfer of the configuration data set signified by the arrow need only take place once for an initialization of the communication between the server device 2 and the power management device 1. The method steps described below can be repeated as often as required after an initial configuration of the power management device 1 through reception of the configuration data set. For the sake of clarity, in FIG. 1, the preparatory data exchange before the optimizing interval 17 at the time points 18, 19, 20, 21 and the optimizing interval 17 between the time points 22 and 23 are shown separately. However, it should be noted that as early as during the optimizing interval 17, a corresponding preparatory communication would take place for a next optimizing interval following subsequently thereto which follows, in particular, immediately after the optimizing interval 17, that is, begins at the time point 23.

The further description of the method assumes that as the target variable which is to be optimized in the method for operating the power management device 1, a CO₂ emission is to be minimized. If an economic incentive is to be created for the operator of the power management device or the operational facility to cooperate in increasing the overall efficiency of a power supply network, in an alternative embodiment of the method it would also be possible, as the target variable, to minimize energy costs, wherein the specification of the information data set described below is carried out by the server device, in particular such that a minimization of the costs for consumed energy or a maximization of the remuneration for supplied energy by the power management device is likely to lead to a rise in the energy efficiency of the power supply network, whereby for example, a CO₂ emission is also indirectly reduced and/or a use of renewable energy types can be promoted.

In the time interval 10, an information data set which should be communicated at the time point 18 to the power management system 1 is established by the server device 2. The information data set describes the temporal variation of a coupling information item which describes a relationship between a load profile of the operational facility and the target variable to be optimized. The coupling information item can describe, in particular, a relationship between an energy consumption described by the load profile and/or an energy generation described by the load profile, and the target variable. This can be, for example, a CO₂ emission per MWh produced or a CO₂ reduction per generated MWh.

The information data set additionally describes a temporal variation of a difference information item which describes the relationship between a difference value which defines the difference between a pre-set specified value for the facility load specified by the load profile for a momentary operating time point in the optimizing interval and a momentary actual value of the facility load and the target variable.

Furthermore, the information data set describes the temporal variation of a tolerance information item which defines a relationship between adjustments of the load profile upwardly and downwardly due to possible load adjustment inquiries and the target variable. An adjustment of the load profile upwardly is to be understood as an increase of the power needed or a reduction of a power provision and an adjustment of the load profile downwardly as the opposite.

Furthermore, the information data set describes the temporal variation of a reactive power information item which defines the relationship between a reactive power of the operational facility in the optimizing interval and the target variable. High reactive power levels of the operational facility can reduce the achievable efficiency in the power supply network and thus increase the CO₂ emission. In addition, they lead to additional costs for a power supplier.

Furthermore, the information data set comprises two power maximum information items which each describe a relationship between a maximum of a power level demanded in a pre-set time interval by the operational facility, and the target variable. The pre-set time interval for one of these two power maximum information items is the time interval defined by the configuration data set and for the other power maximum information item, it is the optimizing interval 17.

Additionally, the information data set describes an offset for the target variable which is relevant in particular when the target variable is optimized dependent upon further boundary conditions or in the context of a multi-factor optimization.

The information items described by the information data set are determined by the server device 2 from statistical information of preceding operating cycles and a model of the power supply network with the operational facilities supplied by the power supply network and through a prediction of factors influencing loads occurring in the power supply network.

In the time interval 13, firstly, a load profile which describes a predicted temporal variation of the facility load of the operational facility during the optimizing interval 17 is calculated by the power management device 1 and, secondly, a tolerance profile which describes a tolerance region of the facility load in the optimizing interval, which can be used toward a load adjustment inquiry by the server device 2 in order to adjust the load profile. The tolerance profile describes for each time point, separate possibilities for deviation from the load profile upwardly and downwardly.

The determination of the load profile takes place by minimizing the target variable under at least one boundary condition. When the CO₂ emission is used as the target variable, therefore, the CO₂ emission is minimized, and making use of a price as the target variable, the price is minimized. The target variable depends upon the load profile to be determined as well as upon the information items transferred with the information data set, specifically, in particular the coupling information, the power maximum information items, the reactive power information and the offset for the target variable. Herein, the coupling information items and the reactive power information, in particular, are time-dependent weighting factors for the calculation of the target variable from the load profile from an energy supply calculated from the load profile or from an energy consumption calculated from the load profile. The tolerance profile is additionally determined dependent upon the tolerance information item. The boundary condition describes, in particular, requirements for the operation of the operational facility, for example a temperature interval within which an air-conditioned room is to be maintained or a minimum production quantity of an industrial plant.

Alternatively, the load profile could also be determined in the context of a multi-factor optimization, wherein aside from the target variable, a further variable is optimized. For example, the target variable can be minimized while one variable which describes the production of an industrial plant is maximized. A multi-factor optimization can be combined with the use of boundary conditions.

In order to determine a tolerance interval, a multi-factor optimization is carried out. The tolerance information item describes ecological and/or economic advantages which are achieved when the tolerance range is made use of in the context of a load adjustment. For example, the tolerance information item can describe a CO₂ reduction or a price saving on a load adjustment by the server device. As a further factor, at least one operational result of the operational facility is evaluated. For example, a weighted total of the product of the tolerance information item and the deviation described in the tolerance profile and a production quantity of an industrial plant can be minimized or maximized.

In order to determine the load profile and the tolerance profile, prediction information which can be determined, for example, by means of a statistical evaluation of preceding operating intervals of the operational facility can additionally be used. The load profile determined and the tolerance profile determined are transferred, as indicated by the arrow 6, to the server device 2.

In the time interval 11, the server device 2 evaluates the transferred load profile of the power management device 1. Further power management devices (not shown) can also calculate load profiles and tolerance profiles and provide them to the server device 2. Dependent upon this data and other information which enables a prediction of power levels or energy levels available in the power supply network, it is checked by the server device 2 whether information items previously transferred by the information data set are to be adjusted, since prognoses over the power levels or energy levels supplied or demanded in the power supply network have changed due to the received information. If this is the case, the information data set is adjusted and, as illustrated by the arrow 7, transferred to the power management device 1, whereupon in the time interval 14, as described in relation to the time interval 13, the power management device calculates an updated load profile and/or an updated tolerance profile and provides it at the time point 21 to the server device 2.

In the optimizing interval 17, control of the operational facility by the power management device 1 takes place dependent upon the load profile previously communicated to the server device 2, as well as the difference information item. In typical usage cases, the actual facility load of an operational facility often deviates from a facility load predicted and transferred as a load profile. For example, the power level of a photovoltaic or wind power plant can vary dependent upon the weather and/or individual elements of the operational facility can have a facility load which is dependent upon a manual operation. If a difference value which specifies the deviation between the specified value for the facility load pre-set by the load profile for the momentary operating time point and a momentary actual value of the facility load differs from zero, the operational facility should typically be controlled such that the difference value is minimized. A strict minimizing of the difference value is, however, often not suitable, since a corresponding adjustment of the facility load can be harmful for an operating result of the operational facility. For example, a production level of an industrial plant can be reduced or particular comfort features of a building can be no longer made available.

It is therefore advantageous for controlling the operational facility to use a multi-factor optimization. As one of the optimizing factors, again, the previously described target variable which can represent a CO₂ consumption or energy costs is optimized. As a further optimizing factor, at least one operating parameter of the operational facility, that is for example, a production quantity or a deviation from a pre-set temperature is taken into account. In addition, boundary conditions can be pre-set. The operation of the operational facility therefore takes place such that weighing up takes place between an optimization of the target variable and operational requirements for the operational facility.

At least during the optimizing interval, acquisition data concerning the facility load of the operational facility are repeatedly transferred by the power management device 1 to the power management device 1. A corresponding transfer also takes place from further power management devices (not shown). In addition, the server device 2 can evaluate predictions for parameters which influence a facility load in the power supply network, as described in relation to the time interval 10. Alternatively or additionally, the power management device 1 can evaluate under what conditions energy can be purchased or sold on electricity markets.

By evaluating these information items, in particular by means of an optimizing algorithm, it can be determined by the server device 2 in some operational situations that an adjustment of the power levels supplied or demanded in the power supply network is suitable. If, for example, a part of the energy supplied in the power supply network is provided by photovoltaic systems and during the original determination of the information data set, in the time intervals 10 or 11 it was indicated by means of prediction data that due to a high sunlight level, a high energy supply level from the photovoltaic systems is to be expected, during the time interval 12, however, a corresponding prediction is updated and it is now expected that the energy supply by the photovoltaic system will be significantly lower, it is likely that insufficient energy will be supplied in the power supply network.

Dependent upon a momentary cost and supply situation on an energy market, this lack of supplied energy can be compensated for in that energy is purchased from an energy market. Frequently, however, this is not suitable ecologically and/or economically, so that it can be advantageous instead to adjust the load profile of the operational facility controlled by the power management device 1.

For this purpose, the tolerance profile which is provided by the power management device 1 to the server device 2 and which describes to what extent an adjustment of the load profile of the operational facility is possible is evaluated. If the tolerance profile shows for a relevant time period that an adjustment of the load profile for lowering the power level demanded by the operational facility is possible, at the time point 24 the server device sends a load adjustment request, as indicated by the arrow 9, to the power management device 1 which adjusts the load profile according to the load adjustment request and executes the further operation of the operational facility in the optimizing interval 17 according to the adjusted load profile.

By means of a corresponding load adjustment request, the load profile can be adjusted such that an energy consumption by the operational facility is reduced and thus a lower level of energy made available, for example, due to the aforementioned lower than expected sunlight level at a photovoltaic system, is compensated.

FIG. 2 shows schematically a power management device 28 for controlling an operational facility 25 connected to a power supply network (not shown). The operational facility 25 serves in the operation of a building 34. The operational facility 25 comprises a plurality of consumers 26 and a photovoltaic system 35 which are controlled by an automation device 27. In order to increase an efficiency of the overall power supply network with the operational facility 25 connected thereto, the behavior of the operational facility 25 at the network connection, that is its facility load, should be coordinated with a device assigned to the power supply network, specifically the server device 31.

The server device 31 also communicates with further operational facilities 33 and acquires their facility load, so that via the server device 31, the respective facility load of the operational facilities 33 and the operational facility 25 can be coordinated to a certain degree. The server device 31 also communicates with a device 32 associated with an energy market in order to adjust the demanded or supplied power levels in the power supply network to conditions on the energy market, in particular dependent upon an energy price, to adjust a purchase and/or a sale of energy.

For the coordination of the network connection behavior of the operational facility 25, the building 34 comprises the power management device 28 which communicates, over a network 30 via a communication module 29 integrated into the power management device 28, for example, the Internet or a VPN, with the server device 31 as described in relation to FIG. 1. The communication between the power management device 28 and the automation device or the server device 31 takes place, respectively, through network-callable functions.

In alternative exemplary embodiments, it would be possible to integrate the power management system 28 into the automation device 27 and/or to configure the communication module 29 separately from the power management device 28, wherein in this case, a communication between the communication module 29 and the power management device 28 can also take place via network-callable functions.

Although the invention has been illustrated and described in detail based on the preferred exemplary embodiment, the invention is not restricted by the examples given and other variations can be derived here from by a person skilled in the art without departing from the protective scope of the invention.

What is claimed is:

1. A method for operating a power management device for controlling an operational facility connected to a power supply network, wherein the maximum power level demanded and/or supplied by the controlled operational facility is at least 3 kW, the method comprising:
a. receiving, from a server device which is associated with a network operator of a power supply network or with a power supplier, an information data set which that describes a coupling information item or a temporal variation of the coupling information, wherein the coupling information describes a relationship between a facility load caused by the operational facility and a target variable to be optimized during an optimizing interval, b. determining, by the power management device, a load profile which describes a predicted temporal variation of the facility load of the operational facility during the optimizing interval, by optimizing the load profile with respect to the target variable,
c. providing the load profile to the server device, and
d. controlling, by the power management device, the operational facility in the optimizing interval based on a specified value for the facility load pre-set by the load profile for a current operating time point.

2. The method of claim 1, wherein steps a) to c) are performed at a pre-set time spacing before the optimizing interval.

3. The method of claim 1, wherein steps a) to c) are performed at a plurality of temporally spaced time points before the optimizing interval.

4. The method of claim 1, wherein the operational facility is controlled by the power management device in the optimizing interval based on a difference value representing a difference between the specified value for the facility load pre-set by the load profile for the current operating time point and a current actual value of the facility load.

5. The method of claim 4, wherein the information data set includes a difference information item or a temporal variation of a difference information item, wherein the difference information item describes a relationship between the difference value and the target variable, wherein the operational facility is controlled based on the target variable.

6. The method of claim 1, wherein the power management device receives a load adjustment request from the server device, and adjusts he load profile based on the load adjustment request.

7. The method of claim 6, wherein the power management system, based on at least one operating parameter influencing the facility load of the operational facility and/or at least one property of the operational facility influencing the facility load of the operational facility, determines and transfers to the server device a tolerance profile defining a temporal variation of a tolerance region of the facility load in the optimizing interval, and
the load adjustment request is determined such that the adjusted load profile lies within the tolerance region defined by the tolerance profile.

8. The method of claim 7, wherein the information data set defines at least one tolerance information item or a temporal variation of the tolerance information, wherein the tolerance information describes a relationship between adjustments of the load profile based on possible load adjustment requests and the target variable, wherein the tolerance profile is determined based on the tolerance information item.

9. The method of claim 1, wherein the information data set defines a power maximum information item that describes a relationship between the target variable and the maximum of a power level in a pre-set time interval supplied and/or demanded by the operational facility, wherein the load profile and/or the control of the operational facility is determined based on the power maximum information item.

10. The method of claim 1, wherein the information data set includes a reactive power information item or a temporal variation of the reactive power information item,
wherein the reactive power information item defines a relationship between a reactive power level of the operational facility and the target variable during the optimizing interval,
wherein the load profile and/or the control of the operational facility is determined based on the reactive power information item.

11. The method of claim 1, comprising:
repeatedly acquiring, by the power management device, acquisition data concerning a facility load of the operational facility at least during the optimizing interval, and
providing the acquisition data to the server device.

12. The method of claim 1, comprising before step a), transferring a configuration data set from the server device to the power management device, and
adjusting, by the power management system the determination of the load profile and/or the determination of the tolerance profile and/or the control of the operational facility based on the configuration data set.

13. The method of claim 12, comprising pre-setting, based on the configuration data set, at least one time point of the provision of the load profile in relation to the optimizing interval and/or a length of the optimizing interval.

14. A power management device for controlling an operational facility connected to a power supply network, wherein the maximum power level demanded and/or supplied by the controlled operational facility is at least 3 kW, wherein said power management device is configured to:
receive, from a server device which is associated with a network operator of a power supply network or with a power supplier, an information data set that describes a coupling information item or a temporal variation of the coupling information wherein the coupling information describes a relationship between a facility load caused by the operational facility and a target variable to be optimized during an optimizing interval,
determine a load profile which describes a predicted temporal variation of the facility load of the operational facility during the optimizing interval, by optimizing the load profile with respect to the target variable,
provide the load profile to the server device, and
control the operational facility in the optimizing interval based on a specified value for the facility load pre-set by the load profile for a current operating time point.

15. A computer program for controlling an operational facility connected to a power supply network, wherein the maximum power level demanded and/or supplied by the controlled operational facility is at least 3 kW, wherein the computer program is stored in non-transitory computer-readably media and executable by a processor associated with the power management device to:
receive, from a server device which is associated with a network operator of a power supply network or with a power supplier, an information data set that describes a coupling information item or a temporal variation of the coupling information wherein the coupling information describes a relationship between a facility load caused by the operational facility and a target variable to be optimized during an optimizing interval,
determine a load profile which describes a predicted temporal variation of the facility load of the operational facility during the optimizing interval, by optimizing the load profile with respect to the target variable,
provide the load profile to the server device, and
control the operational facility in the optimizing interval based on a specified value for the facility load pre-set by the load profile for a current operating time point.
